(19) United States
(12) Patent Application Publication
(10) Pub. No.: US 2005/0207130 A1
(43) Pub. Date: Sep. 22, 2005

(54) Chassis frame

(76) Inventors: Yuan-Chen Liang, Tao Yuan Shien (TW); Cheng-Wang Lin, Panchiao City (TW); Chao-Jung Chen, Taipei (TW); Jen-Hsiang Lee, Taipei (TW)

Correspondence Address: RABIN & BERDO, P.C., Suite 500, 1101 14 Street, Washington, DC, 20005, US

(21) Appl. No.: 11/025,063

(22) Filed: Dec. 30, 2004

(30) Foreign Application Priority Data
Mar. 16, 2004 (TW) 93204003

(51) Int. Cl. H05K 5/04; H05K 9/00

(52) U.S. Cl. 361/752; 361/818; 361/757

(57) ABSTRACT

A chassis frame is described. The chassis frame has a front panel, a backboard, and a plurality of first rigid rods. The rigid rods couple between the front panel and the backboard to enhance the structural strength of the chassis frame. A second rigid rod is utilized to link transversely two of the first rigid rods, a third rigid rod is utilized to link the front panel and the second rigid rod, and the fourth rigid rod is utilized to link the second rigid rod and the backboard. Quick connectors, e.g. U-shaped quick connectors and T-shaped quick connectors, are further utilized to link the rigid rods, the front panel, and the backboard.

### RELATED APPLICATIONS

The present application is based on, and claims priority from, Taiwan Application Serial Number 93204003, filed Mar. 16, 2004, the disclosure of which is hereby incorporated by reference herein in its entirety.

### FIELD OF THE INVENTION

The present invention generally relates to a chassis frame. More particularly, this invention relates to a computer chassis frame.

### BACKGROUND OF THE INVENTION

Information technology and the computer industry are highly developed now. People rely heavily on computer systems. Therefore, computer servers with high calculation capacity and high stability are important for computer systems. Due to increasingly reduced office space, area occupied by computer servers must also be reduced. Computer servers must maintain a high degree of stability to serve users, and the space occupied by one computer server is therefore greater than or equal to that of a desktop computer. Accordingly, the management of computer servers is difficult and space utilization is tightened. Some companies have 2 or 3 computer servers, while others may have more than a thousand computer servers. Computer server management and space utilization become more critical in companies with more computer servers.

A 1U computer server assembled on a standard 1U server rack is the mainstream computer server arrangement. Each standard layer of the rack is about 1.75 inches (about 4.5 centimeters), so that the 1U server and the rack effectively conserve occupational space of the computer servers. Moreover, the 1U servers and racks are more efficiently controlled because the 1U servers and racks can be centrally managed and easily stacked. Normally, hardware used in the 1U server is provided with a smaller size and lower height to fit the thickness limitation of 1.75 inches.

A server system is convenient for users seeking or storing data because the server rack usually provides numerous hard disks and/or other storage mediums to store data therein. Motherboards of the server system, the hard disks and/or the other storage mediums are normally configured in a chassis effectively to provide services for the users. A conventional chassis includes a support panel made of sheet metals for fixing the motherboard, the hard disks and/or the other storage mediums thereon.

However, the sheet metals support panel of the chassis cannot provide enough structural strength to support the increasingly varied internal peripheral devices. Therefore, various enhancing sideboards or structures are designed to improve the structural strength of the sheet metal support panel. Accordingly, a heavier chassis including the enhanced sheet metal support panel makes the total weight of the chassis heavy. Especially in the 1U server, the chassis with the enhanced sheet metal support panel not only occupies quite a large volume in the server racks but also makes the chassis itself heavier.

### SUMMARY OF THE INVENTION

It is an object of the present invention to provide a chassis frame, serving as a support panel, constructed from rigid rods for supporting the motherboards and computer peripheral devices thereon so as to reduce the weight of the chassis.

It is another object of the present invention to provide a chassis frame, serving as a support panel, constructed from rigid rods to reduce chassis sag and increase structural strength of the chassis.

To accomplish the above objectives, the present invention provides a chassis frame having a front panel, a backboard, and a plurality of first rigid rods. The front panel and the backboard provide an electromagnetic shield for electrical devices fixed in the chassis frame. The first rigid rods are coupled between the front panel and the backboard to provide structural strength for the chassis frame.

The chassis frame further utilizes a second rigid rod transversely coupling between two of the first rigid rods to enhance the structural strength of the chassis frame. The chassis further includes a third rigid rod configured between the second rigid rods and the front panel to enhance further the structural strength of the chassis frame. The chassis frame also includes a fourth rigid rod between the second rigid rods and the backboard to enhance further the structural strength of the chassis frame.

The first, second, third and fourth rigid rods are preferably made of a bar or tube material with high structural strength, such as, for example, a bar material or a tube with a round, square, triangular, elliptical or polyhedral cross-section.

The first rigid rod further includes quick connectors disposed at two ends thereof for quickly coupling to the front panel and the backboard. The quick connector is, for example, an U-shaped quick connector. Two perpendicular rigid rods, for example, the first rigid rod and the second rigid rod, can be coupled together by a T-shaped quick connector. Otherwise, two perpendicular rigid rods can be also coupled together by a fixing device such as, for example, a pair of screws or weld.

The chassis frame is preferably a computer chassis frame, more preferably is a computer server chassis frame, and most preferably is a 1U computer server chassis frame. The electrical device, such as, for example, a computer motherboard or an internal computer peripheral device, is fixed on the first, second, third or fourth rigid rods.

Hence, the chassis frame can effectively reduce the weight of the chassis, increase the utilizable space in the chassis frame and improve the structural strength of the chassis frame so as to increase the reliability and safety of the chassis frame and the electrical device fixed therein. The chassis frame can apply to any other electrical apparatus to enhance the shell structural strength thereof and reduce the total weight thereof.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a preferred embodiment of the chassis frame according to the present invention; and

FIG. 2 is a detailed drawing of the preferred embodiment of the chassis frame according to the present invention of FIG. 1.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

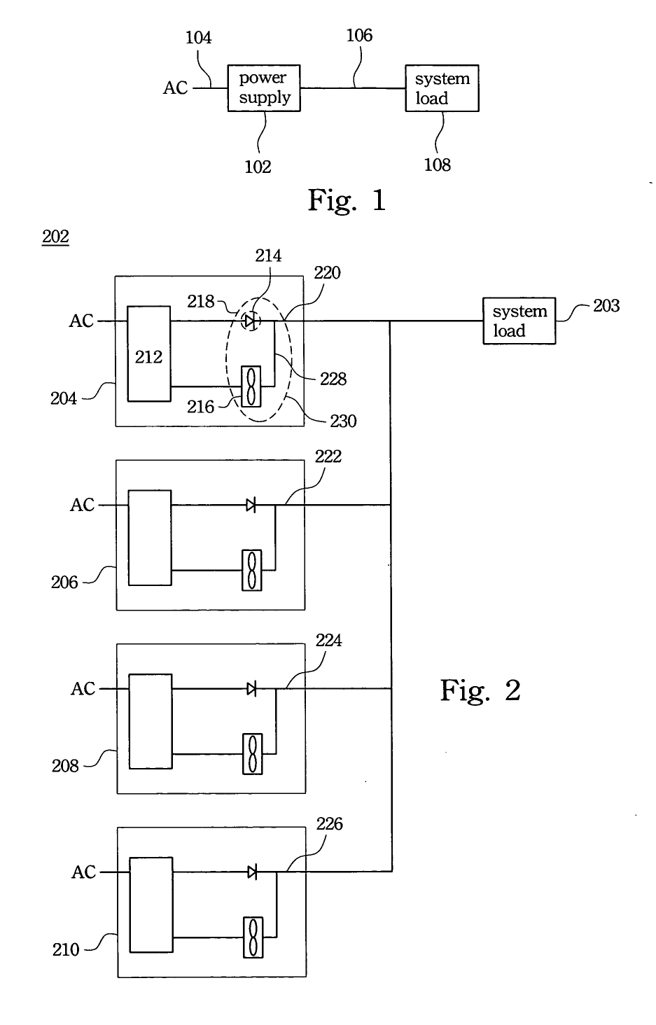

FIG. 1 is a preferred embodiment of the chassis frame according to the present invention. A computer chassis includes a chassis frame 120 and a shell 110. The chassis frame 120 provides an integral rigidity for the computer chassis to protect a motherboard and peripheral devices fixed on the chassis frame 120 while the chassis is in use or in an environment test. The chassis frame 120 according to the present invention utilizes rigid rods to form a rigid frame for enhancing the structural strength of the computer chassis so as to eliminate an unnecessary sheet metal support panel from the computer chassis, thereby reducing the weight of the computer chassis. In addition, the chassis frame 120 constructed of rigid rods can reduce a required volume of the support panel so as to increase an internal utilizable space in the computer chassis, and, in particular, the limited space of the 1U server can be effectively extended.

FIG. 2 is a detailed drawing of the preferred embodiment of the chassis frame according to the present invention. The chassis frame 200 has a front panel 210, a backboard 220 and first rigid rods 230. The first rigid rods 230 connect the front panel 210 and the backboard 220 to provide a main structural strength for the chassis frame 200. The chassis frame 200 further has second rigid rods 250 in a transverse direction to couple with the first rigid rods 230 on both sides of the chassis frame 200 to further increase the structural strength of the chassis frame 200. The chassis frame 200 furthermore has third rigid rods 240 and fourth rigid rods 260 to couple the second rigid rods 250 to the front panel 210 and the backboard 220, respectively, so as to additionally increase the integral structural strength of the chassis frame 200. In particular, a plurality of fixing holes is configured on the foregoing rigid rods for effectively fixing motherboards and/or peripheral devices thereon. Accordingly, the chassis frame 200 can utilizes a small amount of rigid rods to enhance the integral structural strength of the computer chassis, reduce the total weight of the computer chassis, and further increase the internal utilizable space in the computer chassis. In particular, the rigid rods can effectively fix the motherboard and the peripheral devices thereon so as to allow a more convenient and simpler computer assembly process.

The rigid rods are preferably made of a metal bar material or steel beams, such as, for example, round, square, triangular, elliptical or polyhedral metal bars, or round, square, triangle, elliptical or polyhedral metal tubes. The rigid rods can also made of any high structural strength nonmetal bar materials or tubes. The front panel and the backboard can further provide an electromagnetic shield for the motherboard and the internal peripheral devices to be fixed on the chassis frame to protect electrical devices disposed in the chassis frame.

The chassis frame 200 further utilizes a coupling device to couple the rigid rods to the other rigid rods, the front panel 210, or the backboard 220. The coupling device can be an U-shaped quick connector 270, a T-shaped quick connector 280, or any other shape quick connections such as, for example, E-shaped or L-shaped quick connectors. Any shape quick connectors can be utilized in the chassis frame 200 while the quick connections can provide quick connections between the rigid rods, the front panel and the backboard. The coupling device can further utilize a fixing device 290 to couple two rigid rods so as to enhance the integral structural strength of the chassis frame. The fixing device 290 can be a pair of screws or weld to couple effectively the rigid rods and provide an suitable connection structural strength. Additionally, both sides of the front panel 210 further have fixing screws 300 to fix the computer chassis on a server rack.

The chassis frame according to the present application utilizes bar or tube material with high structural strength to decrease a need for sheet metal to form a computer chassis, thereby decreasing the total weight of the computer chassis and providing an extended space in the computer chassis. Furthermore, with rigid rods having high structural strength, the integral structural strength of the computer chassis is also improved. The chassis sag can therefore be reduced by about ⅓ in a finite element analysis and an actual environment test. Accordingly, the chassis frame according to the present invention can provide a preferable chassis structural strength and rigidity to protect effectively the electrical device fixed therein. The chassis frame further conveniently utilizes the quick connectors to couple the rigid rods and reduce the assembly cost. The chassis frame is not limited to a chassis for a computer server, and any electrical apparatus or computers can utilize the chassis frame with the rigid rods to enhance the structural strength thereof and fix electrical device therein.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

1. A chassis frame for a computer, comprising:
a front panel;
a backboard, wherein the front panel and the backboard provide an electromagnetic shield for at least one electrical device fixed in the chassis frame; and
a plurality of first rigid rods coupling the front panel to the backboard to provide structural strength for the chassis frame.

2. The chassis frame of claim 1, wherein the first rigid rod is made of a bar material with high structural strength.

3. The chassis frame of claim 2, wherein the bar material with high structural strength is a metal bar with a round, square, triangular, elliptical or polyhedral cross-section.

4. The chassis frame of claim 1, wherein the first rigid rod is made of a steel beam.

5. The chassis frame of claim 1, wherein the first rigid rod is made of a high structural strength tube.

6. The chassis frame of claim 5, wherein the tube with high structural strength is a metal tube with a round, square, triangular, elliptical or polyhedral cross-section.

7. The chassis frame of claim 5, wherein the chassis frame further comprises a second rigid rod transversely coupling between two of the first rigid rods to enhance the structural strength of the chassis frame.

8. The chassis frame of claim 7, wherein the chassis frame further comprises a third rigid rod coupling the second rigid rods to the front panel to further enhance the structural strength of the chassis frame.

9. The chassis frame of claim 8, wherein the chassis frame further comprises a fourth rigid rod coupling the second rigid rods to the backboard to enhance further the structural strength of the chassis frame.

10. The chassis frame of claim 9, wherein the first rigid rod further comprises quick connectors at two ends of the first rigid rod for quickly coupling to the front panel and the backboard.

11. The chassis frame of claim 10, wherein the quick connector is a U-shaped quick connector.

12. The chassis frame of claim 9, wherein the first rigid rod and the second rigid rod are coupled together by a T-shaped quick connector.

13. The chassis frame of claim 9, wherein the second rigid rod and the fourth rigid rod are coupled together by a fixing device.

14. The chassis frame of claim 13, wherein the fixing device is a pair of screws or a weld.

15. The chassis frame of claim 14, wherein the electrical device is fixed on the first rigid rod, the second rigid rod, the third rigid rod, or the fourth rigid rod.

16. The chassis frame of claim 15, wherein the electrical device is a computer motherboard or an internal peripheral device.

17. The chassis frame of claim 14, wherein the chassis frame is a server chassis frame.

18. The chassis frame of claim 17, wherein the server chassis frame is a 1U server chassis frame.

19. The chassis frame of claim 18, wherein the front panel further comprises a fixing screw to fix the 1U server chassis frame on a server rack.

20. The chassis frame of claim 1, wherein the front panel and the backboard are made of sheet metal material.
